(19) United States
(12) Patent Application Publication
(10) Pub. No.: US 2025/0098196 A1
(43) Pub. Date: Mar. 20, 2025

(54) SEMICONDUCTOR STRUCTURE AND METHOD FOR FORMING THE SAME

(71) Applicant: Taiwan-Asia Semiconductor Corporation, Hsinchu City (TW)

(72) Inventors: Yu-Wei CHANG, Hsinchu City (TW); Tzuen-Yang YE, Hsinchu City (TW)

(21) Appl. No.: 18/626,549

(22) Filed: Apr. 4, 2024

(30) Foreign Application Priority Data
Sep. 19, 2023 (TW) 112135768

(51) Int. Cl. H01L 29/66; H01L 29/20; H01L 29/778

(52) U.S. Cl. CPC H10D 30/015; H10D 30/475; H10D 62/8503

(57) ABSTRACT

The present invention relates to a semiconductor structure and a method for forming the same. The semiconductor structure comprises a substrate, a channel layer, a barrier layer, a source electrode, a gate electrode, a drain electrode, and a cap layer. The channel layer is disposed on the substrate, the barrier layer is disposed on the channel layer, and the source electrode, the gate electrode, and the drain electrode are disposed on the barrier layer. Except the regions directly above the source electrode and the drain electrode, the cap layer covers the source electrode and the drain electrode.

### CROSS-REFERENCES TO RELATED APPLICATIONS

This application claims the benefit of priority to Taiwanese Patent Application No. 112135768 filed on Sep. 19, 2023, which is hereby incorporated by reference in its entirety.

### BACKGROUND OF THE INVENTION

### Field of the Invention

The present invention relates to a semiconductor structure and the method for forming the same, particularly to a structure and its manufacturing method for a high electron mobility transistor (HEMT).

### Descriptions of the Related Art

With the increasing demand for high-frequency and high-power products in recent years, gallium nitride (GaN) semiconductor power devices have gained significant attention. Taking aluminum gallium nitride/gallium nitride (AlGaN/GaN) as an example, these devices exhibit wide bandgap and high electron mobility so very fast switching speeds can be performed. Moreover, they possess characteristics suitable for operation in high-frequency, high-power, and high-temperature environments, Thus, AlGaN/GaN are widely applied in high-power semiconductor structures, especially in RF (radio frequency) and power applications. Traditionally, high-electron-mobility transistors utilize the stacking of III-V semiconductors to form a heterojunction at the interface. The band bending at the heterojunction creates a potential well in the deep bend of the conduction band, forming a two-dimensional electron gas (2DEG) within the potential well.

Generally, high-electron-mobility transistors are normally-on or depletion-mode devices. These depletion-mode devices require an additional negative bias to turn off the device. Apart from being relatively inconvenient to use, this also limits the range of applications for the device. On the other hand, there is another type of enhancement-mode high-electron-mobility transistor that has been proposed. It utilizes fluorine ion bombardment to disrupt the lattice structure of the aluminum gallium nitride layer before forming the metal gate, or forms a recess by etching in the aluminum gallium nitride layer. Subsequently, a gate stack structure is grown in the recess, with a nitrogen-doped gallium nitride layer having a P-type impurity at the bottom of the recess. In this manner, a normally-off or enhancement-mode device can be achieved for turning off the two-dimensional electron gas without the need for an additional bias voltage.

Currently, while manufacturing the two semiconductor devices mentioned above, titanium/aluminum alloy is commonly used as the electrode material for the source and drain electrodes of the devices. A high-temperature heating treatment is required among these two electrode ends and the aluminum gallium nitride barrier layer to form an ohmic contact between the electrodes and the gallium nitride. If the alloy temperature is not higher enough, it is difficult to form an ohmic contact between the electrodes and the gallium nitride. On the other hand, if the alloy temperature is too high, due to the low melting temperature of aluminum in the electrode, metal overflow will be occurred and decrease process yield. As indicated by the dashed lines in FIG. 1, it shows a conceptual diagram of the lateral and upward metal overflow formed during the ohmic contact process of the conventional HEMT device due to high temperature. Please refer to FIG. 1A, which shows an actual microscopic enlarged image of lateral metal overflow. If such lateral metal overflow occurs during the process, it may cause a short circuit between the gate electrode and the source electrode in the subsequent gate electrode formation process. On the other hand, FIG. 1B shows an actual microscopic enlarged image of the upward metal overflow. If upward metal overflow occurs during the process, it will affect the flatness of the metal layer surface, harmful to the subsequent metal stacking process.

To overcome the above problems, there is an urgent need in the industry for an innovative semiconductor structure and manufacturing method to improve the problems related to metal overflow and insufficient flatness in the ohmic contact alloy process mentioned above for enhancing process yield.

### SUMMARY OF THE INVENTION

The main objective of the present invention is to provide an innovative semiconductor structure and manufacturing method to improve the issues related to metal overflow and insufficient flatness in the ohmic contact alloy process during the conventional manufacturing of heterostructure field-effect transistors. The goal is to enhance process yield.

To achieve the above objective, the present invention provides a semiconductor structure comprising a substrate, a channel layer, a barrier layer, a source electrode, a gate electrode, a drain electrode, and a cap layer. The channel layer is disposed on the substrate, the barrier layer is disposed on the channel layer, and the source electrode, the gate electrode, and the drain electrode are disposed on the barrier layer. Except the regions directly above the source electrode and the drain electrode, the cap layer covers the source electrode and the drain electrode.

In one embodiment of the semiconductor structure of the present invention, the materials of the source electrode and the drain electrode are selected from a group consisting of titanium, aluminum, nickel, gold and the combination thereof.

In one embodiment of the semiconductor structure of the present invention, the material of the cap layer is selected from a group consisting of silicon nitride, silicon dioxide, silicon oxynitride and the combination thereof.

In one embodiment of the semiconductor structure of the present invention, the semiconductor structure further comprises a first metal layer, disposed above the source electrode and the drain electrode, and electrically connected to the source electrode and the drain electrode.

In one embodiment of the semiconductor structure of the present invention, the semiconductor structure further comprises a liner layer, covering a portion of the barrier layer, the cap layer, the first metal layer, and the gate electrode except the other portion above the first metal layer.

In one embodiment of the semiconductor structure of the present invention, the material of the liner layer is selected from a group consisting of silicon nitride, silicon dioxide, aluminum nitride, silicon carbide and the combination thereof.

In one embodiment of the semiconductor structure of the present invention, the semiconductor structure further comprises a via structure and a second metal layer, respectively disposed above the first metal layer, and electrically connected to the first metal layer.

In one embodiment of the semiconductor structure of the present invention, the material of the barrier layer comprises AlₓIn_{y}Ga_{(1-x-y)}N, where 0≤x<1, 0≤x+y≤1.

In one embodiment of the semiconductor structure of the present invention, the semiconductor structure further comprises a two-dimensional electron gas, disposed at an interface between the channel layer and the barrier layer.

In one embodiment of the semiconductor structure of the present invention, the material of the substrate is selected from a group consisting of silicon, sapphire, silicon carbide and the combination thereof.

To achieve the above objective, the present invention provides a semiconductor structure comprises a substrate, a channel layer, a barrier layer, a source electrode, a gate electrode, a drain electrode and a conductive cap layer. The channel layer is disposed on the substrate. The barrier layer is disposed on the channel layer. The source electrode, gate electrode, and drain electrode are respectively disposed on the barrier layer. The conductive cap layer covers the source electrode and the drain electrode.

In one embodiment of the semiconductor structure of the present invention, the material of the conductive cap layer is selected from a group consisting of titanium nitride, tungsten nitride, titanium tungsten nitride, aluminum nitride, and carbon and the combination thereof.

In one embodiment of the semiconductor structure of the present invention, the semiconductor structure further comprises a first metal layer, disposed on the conductive cap layer above the source electrode and the drain electrode, and electrically connected to the conductive cap layer, the source electrode, and the drain electrode.

To achieve the above objective, the present invention provides a method of forming a semiconductor structure, the method comprises: forming a channel layer, a barrier layer on a substrate and an interface between the channel layer and the barrier layer having a two-dimensional electron gas; forming a source electrode, a drain electrode, respectively disposed on the barrier layer; forming a cap layer, covering the source electrode and the drain electrode; and heating the source electrode and the drain electrode so that the source electrode and the drain electrode respectively has an ohmic contact with the barrier layer.

In one embodiment of the method of forming a semiconductor structure of the present invention, the method further comprises: forming a gate electrode on the barrier layer between the source electrode and the drain electrode; and forming a first metal layer above the source electrode and the drain electrode, and electrically connecting the first metal layer to the source electrode and the drain electrode respectively.

In one embodiment of the method of forming a semiconductor structure of the present invention, the method further comprises: forming a liner layer, covering the first metal layer and a portion of the barrier layer, the cap layer and the gate electrode; removing a portion of the liner layer above the first metal layer to expose the region above the first metal layer; and annealing the exposed region above the first metal layer.

After reviewing the diagrams and subsequent descriptions, those skilled in the art will readily understand other objectives of the present invention, as well as the technical means and embodiments of the present invention.

### BRIEF DESCRIPTION OF THE DRAWINGS

FIG. 1 illustrates a schematic diagram of lateral and upward metal overflow in the source and drain electrodes of a conventional high electron mobility transistor device.

FIG. 1A illustrates an actual microscopic enlarged image of lateral metal overflow in a conventional high electron mobility transistor device.

FIG. 1B illustrates an actual microscopic enlarged image of upward metal overflow in a conventional high electron mobility transistor device.

FIGS. 2, 3, 4, 5A, 5B, 6, 7, 8 and 9 illustrate the process steps and structural diagrams for forming a semiconductor structure in one embodiment of the present invention.

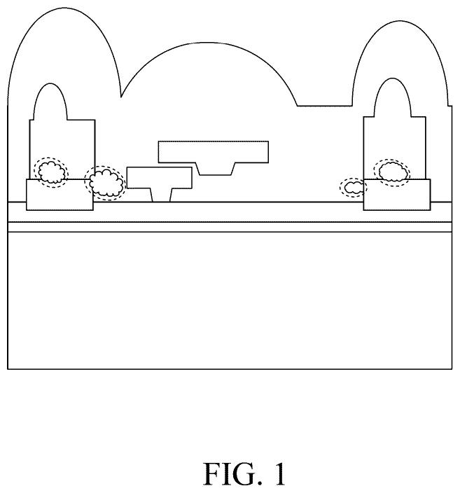

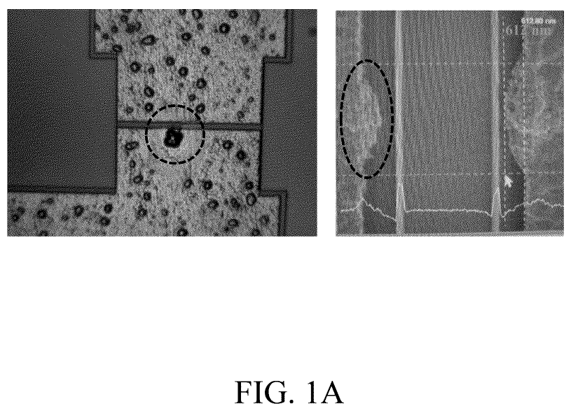

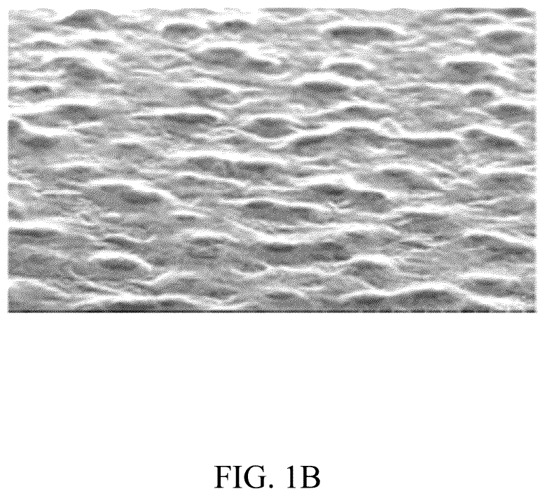

### DETAILED DESCRIPTION OF THE PREFERRED EMBODIMENT

The content of the present invention will be explained through examples below. The examples of the present invention are not intended to limit the implementation of the present invention to any specific environment, application, or particular manner as described in the examples. Therefore, the description of the examples is only to elucidate the purpose of the present invention, and not to limit the present invention. It should be noted that in the following examples and figures, components not directly related to the present invention have been omitted and not shown. The dimensional relationships between the components in the figures are provided for ease of understanding and are not intended to limit the actual proportions.

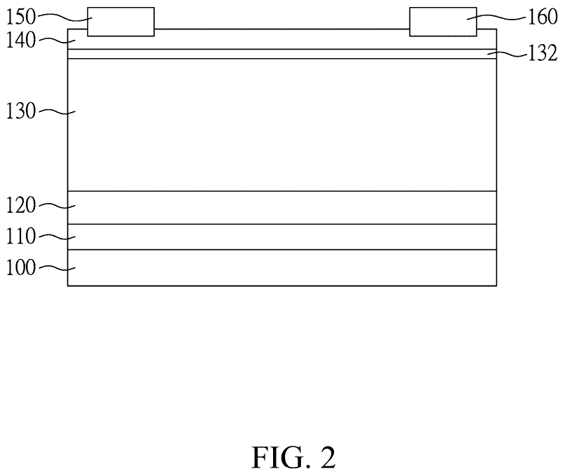

Please refer to FIG. 2, which illustrates a semiconductor structure and its manufacturing method in one embodiment of the present invention. Sequentially formed on a substrate 100 are a nucleation layer 110, a buffer layer 120, a channel layer 130, and a barrier layer 140. The material of the substrate 100 can include silicon, sapphire, gallium nitride, silicon carbide, gallium arsenide, etc. The nucleation layer 110 is located above the substrate 100, with a thickness of about tens or hundreds of nanometers, to reduce the lattice mismatch between the substrate 100 and the barrier layer 140. The nucleation layer 110 may be a III-V material, comprising materials such as aluminum nitride, gallium nitride, or aluminum gallium nitride. The buffer layer 120 is located above the nucleation layer 110, with a thickness of about several micrometers or tens of micrometers. Its material can be III-V materials, also serving to reduce the lattice mismatch between the substrate 100 and the barrier layer 140 and decrease lattice defects. In this embodiment, the buffer layer 120 can include a single-layer structure or a multi-layer structure, such as a multilayer super lattice or a single-layer III-V semiconductor material, comprising materials like aluminum nitride, gallium nitride, or aluminum gallium nitride.

The channel layer 130 is formed on the buffer layer 120 and has a first bandgap. The barrier layer 140 is formed on the channel layer 130 and has a second bandgap, where the second bandgap is higher than the first bandgap, and the lattice constant of the barrier layer 140 is smaller than that of the channel layer 130. In this embodiment, the materials of the channel layer 130 and the barrier layer 140 include aluminum indium gallium nitride (AlₓIn_{y}Ga_{(1-x-y)}N), where 0≤x<1 and 0≤x+y≤1. In this embodiment, the channel layer 130 may be a layer of gallium nitride, while the barrier layer 140 may be a layer of aluminum gallium nitride or indium gallium nitride. Due to the spontaneous polarization in the channel layer 130 and the barrier layer 140 and the piezoelectric polarization between the channel layer 130 and the barrier layer 140, a two-dimensional electron gas 132 is formed at the heterojunction between the channel layer 130 and the barrier layer 140.

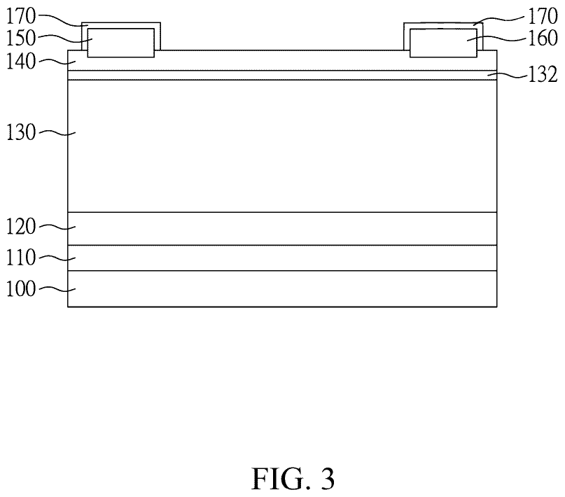

Continuing to FIG. 2, a source electrode 150 and a drain electrode 160 are formed on the barrier layer 140. The materials of the source and drain electrodes can be selected from a group consisting of titanium, aluminum, nickel, gold, and their alloy combination. Next, please refer to FIG. 3, where a cap layer 170 is formed to cover the source electrode 150 and the drain electrode 160. The material of the cap layer 170 can be a hard insulating dielectric material or a hard conductive ceramic material or metal material, for example, selected from a group consisting of silicon nitride, silicon dioxide, silicon oxynitride, titanium nitride, tungsten nitride, titanium tungsten nitride, aluminum nitride, and carbon and the combination thereof. This is to prevent the occurrence of lateral and upward metal overflow during the subsequent high-temperature ohmic contact process between the source electrode 150 and the drain electrode 160. Subsequently, a high-temperature heating process is performed at a temperature of about 850° C. to form ohmic contacts between the metals such as titanium and aluminum of the source electrode 150 and drain electrode 160 and the aluminum gallium nitride of the barrier layer 140. It should be noted that since the source electrode 150 and the drain electrode 160 are already covered by the cap layer 170, even under high temperature, the occurrence of lateral and upward metal overflow, as observed in conventional semiconductor processes due to electrode melting and flow, is prevented. This also avoids potential short-circuit problems between the source electrode and the drain electrode during the subsequent gate structure fabrication. Simultaneously, it prevents adverse effects of upward metal overflow on the source and drain electrodes, ensuring the surface flatness beneficial for subsequent metal stacking processes.

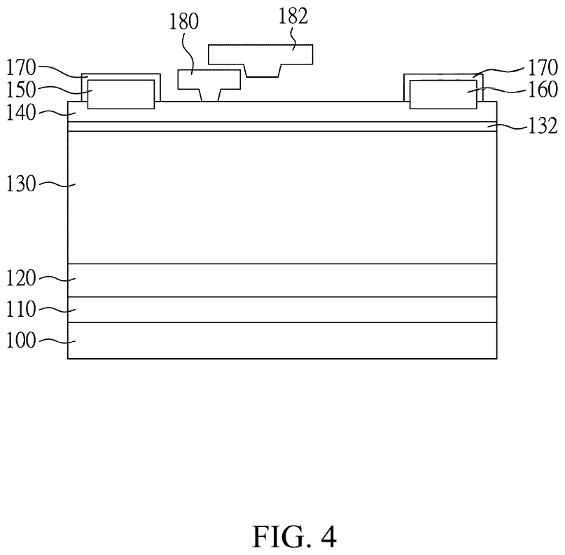

In a specific embodiment, an insulation ion implantation process is then performed between the devices to disrupt the potential two-dimensional electron gas that may exist therebetween. This ensures the insulation independence between various devices on the wafer. Specifically, boron ion beams can be used for insulation ion implantation, with a boron ion concentration controlled at 1E15/cm³ and an ion implantation energy of about 180 KeV. Please refer to FIG. 4, the process of forming the gate electrode is then carried out. A gate electrode 180 is formed on the barrier layer 140 between the source electrode 150 and the drain electrode 160. In a preferred embodiment of the present invention, for further increasing the breakdown voltage and reducing gate leakage current during the fabrication of the gate structure, a field plate structure 182 can be added to the gate structure. It should be emphasized again that in the semiconductor structure disclosed by the present invention, since the periphery of the source electrode 150 and the drain electrode 160 is covered by the cap layer 170, adverse lateral metal overflow during the subsequent high-temperature alloy process for ohmic contact can be avoided. This, in turn, prevents the short-circuit problem between the lateral metal overflow and the gate electrode, thereby improving the process yield.

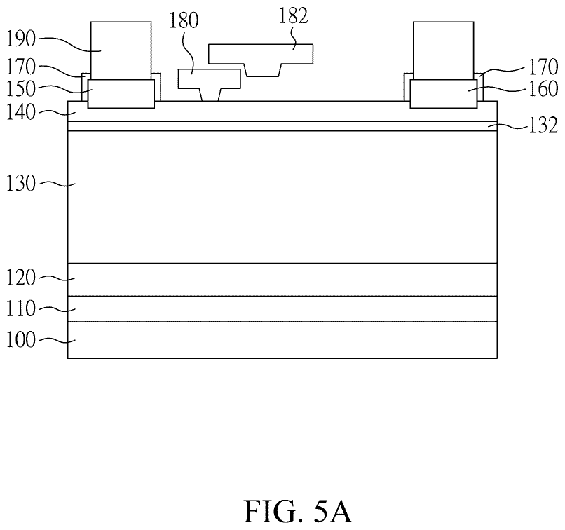

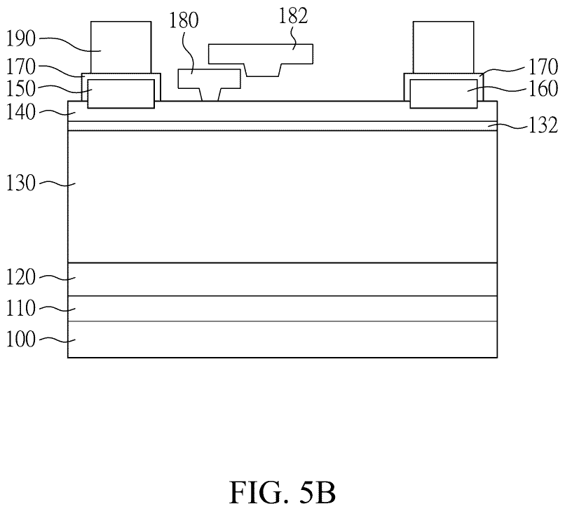

Next, the process of metal stacking above the source electrode and drain electrode is carried out. The metal stacking process at this stage differs depending on the conductivity of the cap layer. As shown in FIG. 5A, when the cap layer 170 is an insulating dielectric material such as the above-mentioned silicon nitride, silicon dioxide, nitrogen-doped silicon oxide, etc., before the metal stacking process, it is necessary to remove a portion of the cap layer 170 above the source electrode 150 and drain electrode 160. This exposes the regions above the source electrode 150 and drain electrode 160, allowing the formation of a first metal layer 190 in the regions above the source electrode 150 and drain electrode 160. The stacking height of the first metal layer 190 must be higher than the height of the gate electrode 180, comprising the field plate 182, to prevent damage to the gate electrode structure during subsequent planarization processes. The material of the first metal layer 190 can include aluminum (Al), copper (Cu), tungsten (W), titanium (Ti), tantalum (Ta), titanium nitride, tantalum nitride, nickel silicide, cobalt silicide, tantalum carbide, tantalum silicon nitride, tantalum carbonitride, titanium aluminum (TiAl), titanium nitride aluminum (TiNAl), metal alloys, or other suitable conductive materials. On the other hand, as shown in FIG. 5B, when the cap layer 170 is a conductive material such as titanium nitride, tungsten nitride, titanium tungsten nitride, aluminum nitride, carbon, etc., and serves as a conductive cap layer, there is no need to remove the cap layer 170 above the source electrode 150 and drain electrode 160 before the metal stacking process. Instead, the first metal layer 190 can be directly formed on the cap layer 170 in the regions above the source electrode 150 and drain electrode 160. Similar to the previous content, the stacking height of the first metal layer 190 must also be higher than the height of the gate electrode 180 and the field plate 182.

It should be noted that while the above processes differ due to the conductivity of the cap layer 170, the subsequent processes of forming semiconductor structure of the present invention are quite similar. For simplicity, the following explanation will be specific to an embodiment with a cap layer 170 having insulating characteristics. Those skilled in the art should be able to easily derive specific embodiments based on a cap layer 170 with conductive properties based on the disclosure of the present invention. Therefore, detailed explanations in this regard are omitted.

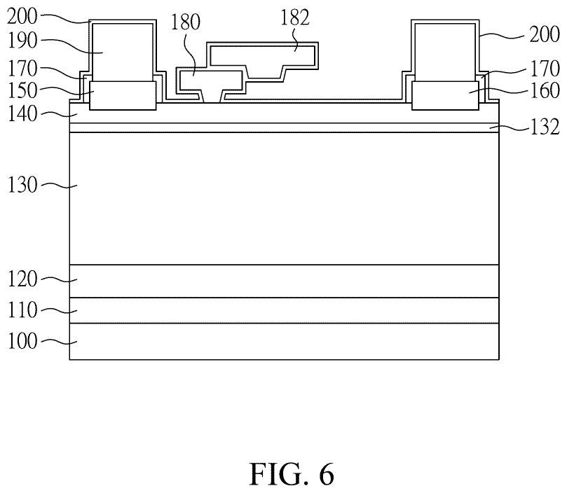

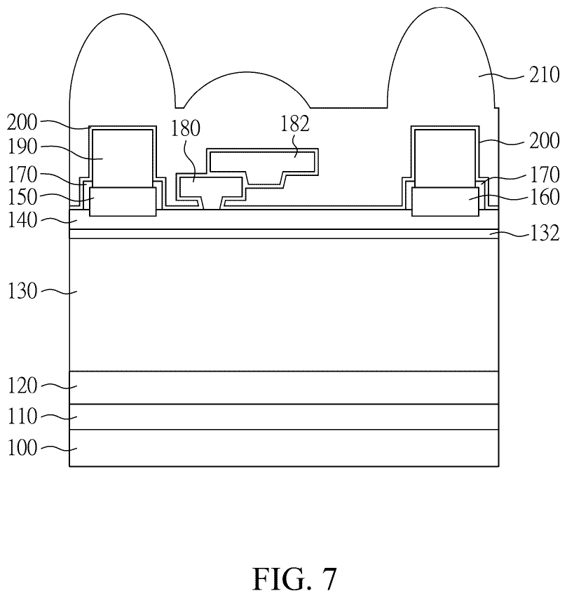

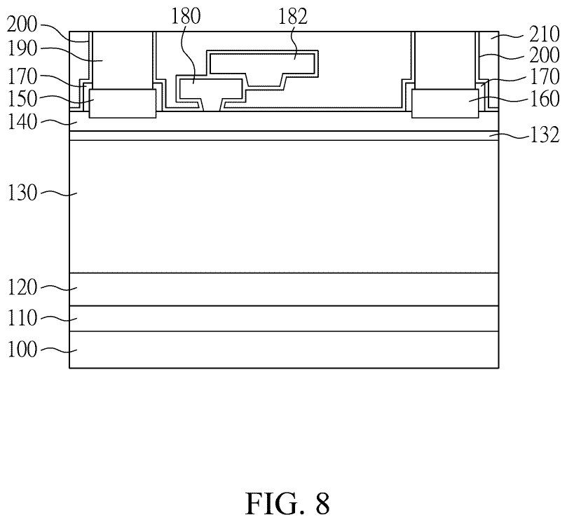

Please refer to FIG. 6, where a liner layer 200 is formed to cover the first metal layer 190 and parts of the barrier layer 140, cap layer 170, and gate electrode 180. Next, as shown in FIG. 7, an inner dielectric layer 210 is formed to cover the entire wafer, followed by a planarization process. Specifically, this planarization process involves chemical-mechanical polishing or wet etching using the liner layer 200 above the first metal layer 190 as a stop layer to remove the liner layer 200 above the first metal layer 190 and expose the region above the first metal layer 190, as shown in FIG. 8. It should be noted that since the metal stack height of the first metal layer 190 is higher than the height of the gate electrode 180 and field plate 182, the planarization process stops at the liner layer 200 above the first metal layer 190. Therefore, this planarization process does not damage the gate electrode 180 and field plate 182. Subsequently, a high-temperature annealing process is performed to flatten the exposed region above the first metal layer 190. In a preferred embodiment, the surface flatness of the region above the first metal layer 190 after high-temperature annealing can be less than 0.1 micrometers, facilitating the subsequent metal stacking process.

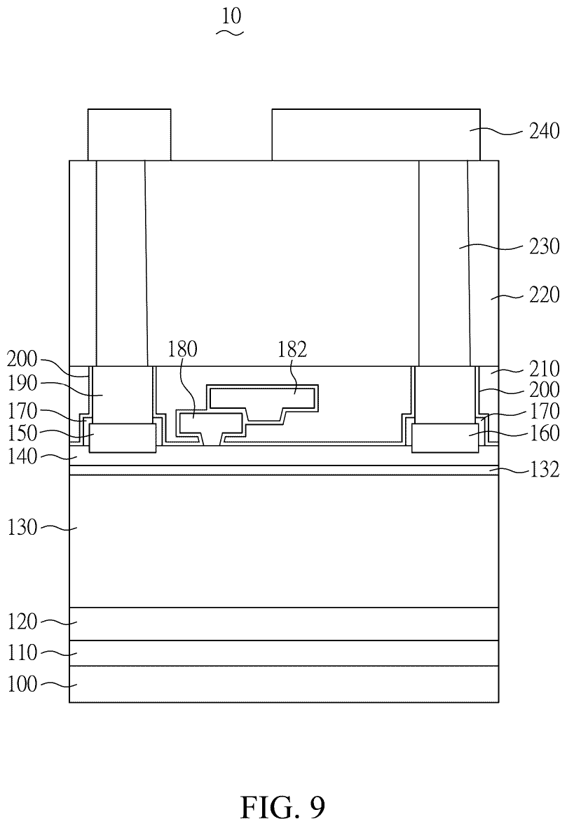

Please refer to FIG. 9, where the interconnection process for the metal stack of the electrodes is carried out. A dielectric layer 220 is formed on the liner layer 200, followed by the formation of a via structure 230 in the dielectric layer 220. Finally, a second metal layer 240 is formed to electrically connect with the via structure 230 and the first metal layer 190, respectively, to electrically connect the source electrode 150 and drain electrode 160, thus completing the semiconductor structure 10 of the present invention. The materials of the via structure 230 and the second metal layer 240 can be the same as the first metal layer 190, and are not further described here.

It should be noted that the above description is only one embodiment of the present invention. The disclosed structures of the present invention can be applied to normally-on or normally-off devices in high electron mobility transistors. For example, in normally-on devices, commonly used gate structures include Schottky gate structures and Metal-Insulator-Semiconductor (MIS) gate structures. In normally-off devices, common gate structures include recessed gate structures and P-type doped gallium nitride (pGaN) gate structures. When fabricating these different gate structures, the insulating function of the disclosed covering layer 170 of the present invention can be applied. This ensures that in the fabrication processes of these devices, there will be no lateral metal overflow from the source electrode, preventing short circuits between the source and gate electrodes. It also ensures the flatness of the metal electrode surface in subsequent metal stacking processes, thereby increasing process yield.

The above embodiments are provided for illustrative purposes and to explain the technical features of the present invention, and are not intended to limit the scope of protection of the present invention. Any modifications or equivalents that can be easily made by those skilled in the art are within the scope claimed by the present invention, and the scope of protection of the present invention shall be determined by the scope of the patent application.

What is claimed is:

1. A semiconductor structure, comprising:
a substrate;
a channel layer, disposed on the substrate;
a barrier layer, disposed on the channel layer;
a source electrode, a gate electrode, a drain electrode, respectively disposed on the barrier layer; and
a cap layer, wherein the conductive cap layer covers the source electrode and the drain electrode except the regions directly above the source electrode and the drain electrode.

2. The semiconductor structure of claim 1, wherein the materials of the source electrode and the drain electrode are selected from a group consisting of titanium, aluminum, nickel, gold and a combination thereof.

3. The semiconductor structure of claim 1, wherein the material of the cap layer is selected from a group consisting of silicon nitride, silicon dioxide, silicon oxynitride and a combination thereof.

4. The semiconductor structure of claim 1, further comprising a first metal layer, disposed above the source electrode and the drain electrode, and electrically connected to the source electrode and the drain electrode.

5. The semiconductor structure of claim 4, further comprising a liner layer, covering a portion of the barrier layer, the cap layer, the first metal layer, and the gate electrode except the other portion above the first metal layer.

6. The semiconductor structure of claim 5, wherein the material of the liner layer is selected from a group consisting of silicon nitride, silicon dioxide, aluminum nitride, silicon carbide and a combination thereof.

7. The semiconductor structure of claim 4, further comprising a via structure and a second metal layer, respectively disposed above the first metal layer, and electrically connected to the first metal layer.

8. The semiconductor structure of claim 1, further comprising a two-dimensional electron gas, disposed at an interface between the channel layer and the barrier layer.

9. The semiconductor structure of claim 1, wherein the material of the barrier layer comprises AlₓIn_{y}Ga_{(1-x-y)}N, where 0≤x<1, 0≤x+y≤1.

10. The semiconductor structure of claim 1, wherein the material of the substrate is selected from a group consisting of silicon, sapphire, silicon carbide and a combination thereof.

11. A semiconductor structure, comprising:
a substrate;
a channel layer, disposed on the substrate;
a barrier layer, disposed on the channel layer;
a source electrode, a gate electrode, a drain electrode, respectively disposed on the barrier layer; and
a conductive cap layer, wherein the conductive cap layer covers the source electrode and the drain electrode.

12. The semiconductor structure of claim 11, wherein the material of the conductive cap layer is selected from a group consisting of titanium nitride, tungsten nitride, titanium tungsten nitride, aluminum nitride, and carbon and a combination thereof.

13. The semiconductor structure of claim 11, further comprising a first metal layer, disposed on the conductive cap layer above the source electrode and the drain electrode, and electrically connected to the conductive cap layer, the source electrode, and the drain electrode.

14. A method of forming a semiconductor structure, comprising:
forming a channel layer, a barrier layer on a substrate and an interface between the channel layer and the barrier layer having a two-dimensional electron gas;
forming a source electrode, a drain electrode, respectively disposed on the barrier layer;
forming a cap layer, covering the source electrode and the drain electrode; and
heating the source electrode and the drain electrode so that the source electrode and the drain electrode respectively has an ohmic contact with the barrier layer.

15. The method of forming a semiconductor structure of claim 14, further comprising:
forming a gate electrode on the barrier layer between the source electrode and the drain electrode; and
forming a first metal layer above the source electrode and the drain electrode, and electrically connecting the first metal layer to the source electrode and the drain electrode respectively.

16. The method of forming a semiconductor structure of claim 15, further comprising:
forming a liner layer, covering the first metal layer and a portion of the barrier layer, the cap layer and the gate electrode;
removing a portion of the liner layer above the first metal layer to expose the region above the first metal layer; and
annealing the exposed region above the first metal layer.
